(19) United States
(12) Patent Application Publication
(10) Pub. No.: US 2026/0103621 A1
(43) Pub. Date: Apr. 16, 2026

(54) METHOD OF PRODUCING POLISHING COMPOSITION AND POLISHING COMPOSITION

(71) Applicant: FUJIMI INCORPORATED, Kiyosu-shi, Aichi (JP)

(72) Inventors: Takehiko MURASE, Kiyosu-shi, Aichi (JP); Kohsuke Tsuchiya, Kiyosu-shi, Aichi (JP); Hisanori Tansho, Kiyosu-shi, Aichi (JP)

(73) Assignee: FUJIMI INCORPORATED, Kiyosu-shi, Aichi (JP)

(21) Appl. No.: 19/116,162

(22) PCT Filed: Sep. 26, 2023
(86) PCT No.: PCT/JP2023/034854

§ 371 Date: Mar. 27, 2025

(30) Foreign Application Priority Data
Sep. 30, 2022 (JP) 2022-158494

(51) Int. Cl. C09G 1/02; H10P 52/00

(52) U.S. Cl. CPC C09G 1/02; H10P 52/00

(57) ABSTRACT

In terms of composition containing a cellulose derivative, provided are a polishing composition, a substrate protective agent, and a method of producing the same that are effective for reducing post-polishing surface defects. Provided is a method of producing a polishing composition containing an abrasive, a basic compound, a cellulose derivative, and a surfactant. The method includes a step (A) of dissolving a material cellulose derivative in a solvent to prepare a material cellulose derivative solution; and the following steps: a step (B1) of heating the material cellulose derivative solution and a step (B2) of adding a material surfactant to the material cellulose derivative solution that underwent the step (B1); or a step (C1) of adding a material surfactant to the material cellulose derivative solution to prepare an additive mixture liquid and a step (C2) of heating the additive mixture liquid.

### TECHNICAL FIELD

The present invention relates to a method of producing a polishing composition and a polishing composition. The application claims the priority based on Japanese Patent Application No. 2022-158494, filed on Sep. 30, 2022, the content of which is herein incorporated by reference in its entirety.

### BACKGROUND ART

A surface of a material such as metal, semimetal, non-metal, or an oxide thereof has been finely polished with a polishing composition. For example, a surface of a silicon wafer used as a component of a semiconductor device or the like is generally finished into a high-grade mirror plane via a lapping step (rough polishing step) and a polishing step (fine polishing step). The polishing step typically includes a stock polishing step and a final polishing step. Patent Documents 1 and 2 are exemplary technical references of a polishing composition mainly used in application of polishing a semiconductor substrate such as a silicon wafer.

### CITATION LIST

### Patent Literature

[Patent Document 1] Japanese Patent Application Publication No. 2012-89862
[Patent Document 2] Japanese Patent Application Publication No. 2015-124231

### SUMMARY OF INVENTION

### Technical Problem

Polishing compositions used for polishing a semiconductor substrate such as a silicon wafer or other substrates (e.g., polishing compositions used for a final polishing step) are required to have performance to provide a surface with low haze and less surface defects after polishing. Several of such polishing compositions contain, in addition to an abrasive and water, a water-soluble polymer for the purpose of improving protection, wettability, etc. of a surface of an object to be polished. In particular, a common water-soluble polymer can be a cellulose derivative.

However, a cellulose derivative is originated from cellulose, a natural product, as a material and thus likely to vary in quality. Therefore, a polishing composition with composition containing a cellulose derivative has conventionally had a difficulty in accurately suppressing micro aggregation potentially causing a surface defect. For example, Patent Documents 1 and 2 describe techniques for reducing surface defects in terms of a polishing composition employing hydroxyethyl cellulose (HEC), but even such techniques sometimes fail to sufficiently meet a recent required level for a quality of a polished surface.

Hence, the present invention has an objective to provide a method of producing a polishing composition, a method of producing a substrate protective agent, a substrate protective agent, and a polishing composition that are effective for reducing post-polishing surface defects, in terms of composition containing a cellulose derivative.

### Solution to Problem

The specification provides a method of producing a polishing composition containing an abrasive, a basic compound, a cellulose derivative, and a surfactant. The method of producing a polishing composition includes a step (A) of dissolving a material cellulose derivative in a solvent to prepare a material cellulose derivative solution; and the following steps: a step (B1) of heating the material cellulose derivative solution and a step (B2) of adding a material surfactant to the material cellulose derivative solution that underwent the step (B1); or a step (C1) of adding a material surfactant to the material cellulose derivative solution to prepare an additive mixture liquid and a step (C2) of heating the additive mixture liquid.

Such a method of producing a polishing composition facilitates providing a polishing composition with reduction in the number and/or amount of coarse particles originated from a cellulose derivative. Such a polishing composition can effectively reduce post-polishing surface defects (e.g., LPD-N) as well as leverage an advantage of use of a cellulose derivative.

In some embodiments, the material surfactant is added at a raised temperature higher than room temperature in the step (B2) or the step (C1). Addition of a material surfactant heated to an appropriate temperature helps reduce the number and/or amount of coarse particles originated from a cellulose derivative.

The specification also provides a method of producing a substrate protective agent containing a cellulose derivative and a surfactant. The method of producing a substrate protective agent includes a step (A) of dissolving a material cellulose derivative in a solvent to prepare a material cellulose derivative solution; and the following steps: a step (B1) of heating the material cellulose derivative solution and a step (B2) of adding a material surfactant to the material cellulose derivative solution that underwent the step (B1); or a step (C1) of adding a material surfactant to the material cellulose derivative solution to prepare an additive mixture liquid and a step (C2) of heating the additive mixture liquid. With such a configuration, a method of producing a substrate protective agent facilitates production of a substrate protective agent with reduction in the number and/or amount of coarse particles originated from a cellulose derivative. Use of such a substrate protective agent can effectively reduce post-polishing surface defects (e.g., LPD-N) as well as leverage an advantage of use of a cellulose derivative.

The specification further provides a substrate protective agent containing a cellulose derivative and a surfactant. The term of substrate protective agent refers to a group of substances that can be absorbed onto at least a surface of a substrate to be polished and adjusting its polishing performance in polishing with use of a polishing composition. The substrate protective agent is prepared by a method including a step (A) of dissolving a material cellulose derivative in a solvent to prepare a material cellulose derivative solution; and the following steps: a step (B1) of heating the material cellulose derivative solution and a step (B2) of adding a material surfactant to the material cellulose derivative solution that underwent the step (B1); or a step (C1) of adding a material surfactant to the material cellulose derivative solution to prepare an additive mixture liquid and a step (C2) of heating the additive mixture liquid.

A substrate protective agent with such a configuration tends to lead to reduction in the number and/or amount of coarse particles originated from a cellulose derivative in the substrate protective agent. Use of such a substrate protective agent can effectively reduce post-polishing surface defects (e.g., LPD-N) as well as leverage an advantage of use of a cellulose derivative.

The specification provides a polishing composition containing an abrasive, a basic compound, and a substrate protective agent. The substrate protective agent contains a cellulose derivative and a surfactant, and is prepared by the following method. In other words, the substrate protective agent is prepared by a method including a step (A) of dissolving a material cellulose derivative in a solvent to prepare a material cellulose derivative solution; and the following steps: a step (B1) of heating the material cellulose derivative solution and a step (B2) of adding a material surfactant to the material cellulose derivative solution that underwent the step (B1); or a step (C1) of adding a material surfactant to the material cellulose derivative solution to prepare an additive mixture liquid and a step (C2) of heating the additive mixture liquid.

Such a polishing composition leads to reduction in the number and/or amount of coarse particles originated from a cellulose derivative in the composition, and thus can effectively reduce post-polishing surface defects as well as leverages an advantage of use of a cellulose derivative. Such a polishing composition is effective for reduction in defects incapable of being solved by treatment such as polishing, cleaning, and drying, which are referred to as e.g., light point defects non-cleanable (LPD-N).

The polishing composition and/or substrate protective agent disclosed herein can be preferably used for polishing of a surface formed of a silicon material. Polishing for a surface formed of a silicon material with use of the polishing composition and/or the substrate protective agent can offer a high-quality surface (e.g., with reduced LPD-N) formed of a silicon material. The substrate protective agent disclosed herein can also be preferably used for rinsing a surface formed of a silicon material.

The polishing composition disclosed herein may be a concentrate. The polishing composition disclosed herein may be produced, distributed, and stored in a concentrate form.

In some embodiments, a polishing method including polishing a surface formed of a silicon material with use of the polishing composition and/or the substrate protective agent is provided. The polishing method can offer a high-quality surface (e.g., with reduced LPD-N) formed of a silicon material.

### DESCRIPTION OF EMBODIMENTS

Preferred embodiments of the present invention will be described below. Matters that are other than those particularly mentioned herein but are necessary for implementation of the present invention can be recognized as matters to be designed by those skilled in the art based on conventional technologies in the art. The present invention can be implemented based on contents disclosed herein and common technical knowledge in the art. Unless otherwise stated, the term “room temperature” as used herein refers to a temperature of 20° C. or higher and 25° C. or lower.

### <Polishing Composition, Substrate Protective Agent, and Methods of Producing the Same>

An embodiment of the present invention relates to a substrate protective agent containing a cellulose derivative and a surfactant. In a preferred embodiment, a method of producing the substrate protective agent includes a step (A) of dissolving a material cellulose derivative in a solvent to prepare a material cellulose derivative solution, a step (B1) of heating the material cellulose derivative solution and a step (B2) of adding a material surfactant to the material cellulose derivative solution that underwent the step (B1)

In another preferred embodiment, a method of producing the substrate protective agent includes a step (A) of dissolving a material cellulose derivative in a solvent to prepare a material cellulose derivative solution, a step (C1) of adding a material surfactant to the material cellulose derivative solution to prepare an additive mixture liquid and a step (C2) of heating the additive mixture liquid.

Furthermore, an embodiment of the present invention relates to a polishing composition containing an abrasive, a basic compound, a cellulose derivative, and a surfactant. The polishing composition has a character of containing a substrate protective agent prepared by any of the methods disclosed herein. In some embodiments, a method of producing the polishing composition further includes a step (D) of mixing the substrate protective agent prepared above, an abrasive, and a basic compound.

A mechanism how the present invention provides a polishing composition and/or substrate protective agent effective for reducing post-polishing surface defects is not particularly limited, and for example, can be estimated as follows.

In the art disclosed herein, a solution containing a material cellulose derivative may be heat-treated, followed by addition of a material surfactant to the material cellulose derivative solution thus heat-treated. Alternatively, in the art disclosed herein, an additive mixture liquid containing a material cellulose derivative and a material surfactant may be heat-treated. The heat treatment tends to attenuate intermolecular hydrogen bonding in a material cellulose derivative and solve molecular aggregation and entanglement. Presence of a material surfactant together with a material cellulose derivative at such a state causes the material surfactant to suitably act on the material cellulose derivative and suppress reaggregation. Such a treatment facilitates solving aggregation, entanglement, or the like of a material cellulose derivative, further suppressing regeneration of an associate, and retaining a dispersion state. These can result in reduction in the size and/or amount of associates originated from a material cellulose derivative and potentially causing a surface defect. Such a polishing composition and/or substrate protective agent is expected to provide reduction in the number of post-polishing surface defects (e.g., LPD-N).

Description will now be made for a polishing composition and/or substrate protective agent and a method of producing the same, but the present invention is not limited to the following description.

Note that the polishing composition and/or substrate protective agent disclosed herein contains a cellulose derivative and a surfactant. As used herein, each of a cellulose derivative and a surfactant used in a process of producing the polishing composition and/or substrate protective agent may be referred to as “material cellulose derivative” and “material surfactant”. In the specification, “material cellulose derivative” can be replaced with “cellulose derivative”, and “material surfactant” can be replaced with “surfactant”.

### (Material Cellulose Derivative)

The material cellulose derivative (or cellulose derivative; the same applies hereinafter) disclosed herein is a polymer containing a β-glucose unit as a main repeating unit. Specific examples of the material cellulose derivative include hydroxyethyl cellulose (HEC), hydroxypropyl cellulose, hydroxyethylmethyl cellulose, hydroxypropylmethyl cellulose, methylcellulose, ethylcellulose, ethylhydroxyethyl cellulose, and carboxy methylcellulose. The material cellulose derivative can be used singly or in combination of two or more kinds thereof. A cellulose derivative in this context refers to a substance derived by replacing a part of hydroxyl groups in cellulose with another substituent(s). Particularly, in view of improving a surface quality after polishing, hydroxyethyl cellulose (HEC) can be preferably used as the cellulose derivative.

Without particular limitation, the material cellulose derivative is preferably a polymer originated from a natural product. A naturally-occurring polymer has limitation in purity, control of contaminants, and the like, and thus is likely to gain an effect from the art disclosed herein.

The weight-average molecular weight (Mw) of the material cellulose derivative (or cellulose derivative) is not particularly limited. In view of protectivity of a surface to be polished and improved polishing performance, the Mw of the material cellulose derivative (or cellulose derivative) is usually, suitably 0.5×10⁴ or more, preferably 1×10⁴ or more, more preferably 10×10⁴ or more. In an even more preferred embodiment, the Mw is, e.g., 15×10⁴ or more, and further may be 20×10⁴ or more, or 25×10⁴ or more. In view of filterability, the Mw of the material cellulose derivative (or cellulose derivative) can also be approximately 300×10⁴ or less, and is suitably 150×10⁴ or less. The Mw may be, e.g., 100×10⁴ or less, 50×10⁴ or less, or 40×10⁴ or less.

As the Mw of a material cellulose derivative herein, a value based on gel permeation chromatography (GPC) (aqueous phase, on polyethylene oxide conversion basis) can be employed. As a GPC measurement device, the machine named “HLC-8320GPC” manufactured by Tosoh Corporation can be used. Measurement conditions can be as follows. The same method is also employed to the examples described later.

### [GPC Measurement Conditions]

Sample concentration: 0.1% by weight
Column: TSKgel GMPWXL
Detector: differential refractometer
Elution liquid: 0.1 mol/L NaNO₃ aqueous solution
Flow rate: 1.0 mL/min
Measurement temperature: 40° C.
Sample injection volume: 200 μL

According to an embodiment of the present invention, the content of a material cellulose derivative in a material cellulose derivative solution is preferably 0.5% by weight or more, more preferably 0.75% by weight or more, even more preferably 1.0% by weight or more. In an embodiment of the present invention, the content of a material cellulose derivative in a material cellulose derivative solution is, in view of solubility, preferably 4% by weight or less, more preferably 3% by weight or less, even more preferably 2% by weight or less.

As a material cellulose derivative according to an embodiment of the present invention, a powder form is preferably used.

### (Material Surfactant)

In a method of producing the polishing composition and/or substrate protective agent disclosed herein, a material surfactant (or surfactant; the same applies hereinafter) is used. Use of a material surfactant tends to lead to suppression of generation of an associate originated from a cellulose derivative, and reduction in defects on a polishing surface (e.g., LPD-N). As the material surfactant, any of anionic, cationic, nonionic, or amphoteric substance is available. Usually, an anionic or nonionic material surfactant can be preferably employed. In view of reduction in haze and in view of low foamability, ease of pH adjustment, etc., a nonionic material surfactant is more preferred. Examples thereof include nonionic surfactant including oxyalkylene polymers such as polyethylene glycol, polypropylene glycol, and polytetramethylene glycol; polyoxyalkylene derivatives (e.g., polyoxyalkylene adducts) such as polyoxyethylene alkyl ether, polyoxyethylene alkyl phenylether, polyoxyethylene alkyl amine, polyoxyalkylenealkyl glucoside, polyoxyethylene fatty acid ester, polyoxyethylene glycerylether fatty acid ester, and polyoxyethylene sorbitan fatty acid ester; and copolymers of plural kinds of oxyalkylene (e.g., diblock type copolymers, triblock type copolymers, random type copolymers, and alternating copolymers). The material surfactant can be used singly or in combination of two or more kinds thereof.

Specific examples of the nonionic surfactant include block copolymers of ethylene oxide (EO) and propylene oxide (PO) (diblock type copolymers, PEO (polyethylene oxide)-PPO (polypropylene oxide)-PEO type triblock forms, PPO-PEO-PPO type triblock copolymers, etc.), random copolymers of EO and PO, polyoxyethylene glycol, polyoxyethylene propylether, polyoxyethylene butylether, polyoxyethylene pentylether, polyoxyethylene hexylether, polyoxyethylene octylether, polyoxyethylene-2-ethylhexylether, polyoxyethylene nonylether, polyoxyethylene decylether, polyoxyethylene isodecylether, polyoxyethylene tridecylether, polyoxyethylene laurylether, polyoxyethylene cetylether, polyoxyethylene stearylether, polyoxyethylene isostearylether, polyoxyethylene oleylether, polyoxyethylene phenylether, polyoxyethylene octylphenylether, polyoxyethylene nonylphenylether, polyoxyethylene dodecylphenylether, polyoxyethylene styrated phenylether, polyoxyethylene laurylamine, polyoxyethylene stearylamine, polyoxyethylene oleylamine, polyoxyethylene methylglucoside, polyoxypropylene methylglucoside, polyoxyethylene monolaurate, polyoxyethylene monostearate, polyoxyethylene distearate, polyoxyethylene monooleate, polyoxyethylene dioleate, polyoxyethylene sorbitan monolaurate, polyoxyethylene sorbitan monopalmitate, polyoxyethylene sorbitan monostearate, polyoxyethylene sorbitan monooleate, polyoxyethylene sorbitan trioleate, polyoxyethylene sorbit tetraoleate, polyoxyethylene castor oil, polyoxyethylene castor wax, and ethylenediamine tetrapolyoxyethylene polyoxypropylene (poloxamine). More suitable examples of the surfactant include block copolymers of EO and PO (in particular, PEO-PPO-PEO type triblock copolymers), random copolymers of EO and PO, and polyoxyethylene alkyl ether (e.g., polyoxyethylene decylether). As such polyoxyethylene alkyl ether, a substance with about 1 to 10 (e.g., about 3 to 8) moles of EO added can be suitably employed.

The molecular weight of the material surfactant (or surfactant) is, e.g., less than 5000, and in view of reduction in aggregates of a cellulose derivative or in view of filterability, cleanability, etc., the molecular weight is preferably 4500 or less, and may be, e.g., less than 4000. In view of interfacial action or the like, the molecular weight of the material surfactant is also usually suitably 200 or more, and in view of an effect to reduce haze or the like, the molecular weight is preferably 250 or more (e.g., 300 or more). The more preferred range of the molecular weight of the material surfactant may also be varied corresponding to the type of the material surfactant. For example, when polyoxyethylene alkyl ether is used as the material surfactant, the molecular weight is preferably e.g., less than 2000, more preferably 1900 or less (e.g., less than 1800), even more preferably 1500 or less, and may be 1000 or less (e.g., 500 or less). In addition, for example, when a block copolymer of EO and PO is used as the material surfactant, the weight average molecular weight thereof may be, e.g., 500 or more, 1000 or more, and further 1500 or more, 2000 or more, and further 2500 or more. The upper limit of the weight average molecular weight is, e.g., less than 5000, preferably 4500 or less, and may be, e.g., less than 4000, less than 3800, or less than 3500.

As the molecular weight of the material surfactant (or surfactant), a molecular weight calculated from a chemical formula may be employed, or a value of a weight average molecular weight derived by GPC (aqueous phase, on polyethylene glycol conversion basis) may be employed. A measurement condition of GPC can employ the same measurement condition as that for the cellulose derivative as described above. For example, polyoxyethylene alkyl ether preferably employs a molecular weight calculated from a chemical formula, and a block copolymer of EO and PO preferably employs a weight average molecular weight derived by the GPC as described above.

### (Solvent)

The solvent disclosed herein is not particularly limited if capable of dissolving a material cellulose derivative, but preferably contains water. In the solvent(s), water preferably accounts for 90% by volume or more, more preferably 95% by volume or more (e.g., 99 to 100% by volume). Examples of water to be potentially preferably used include ion-exchanged water (deionized water), pure water, ultrapure water, and distilled water. In water to be used, the content of transition metal ions is preferably, e.g., 100 ppb or less in total, in order to avoid inhibiting a function of another component in the polishing composition and/or substrate protective agent as much as possible. For example, water can have improved purity by removal of impurity ions by ion-exchange resin, removal of contaminants by a filter, distillation, etc.

The solvent may also be an organic solvent, or a mixture solvent of water and an organic solvent. The organic solvent is not particularly limited, and known organic solvents can be used. In use of a mixture solvent of water and an organic solvent, preferably employed are organic solvents miscible with water such as lower alcohol and lower ketone. These organic solvents can be used singly or in combination of two or more kinds thereof.

### <Step (A) of Preparation of Material Cellulose Derivative Solution>

The polishing composition and/or substrate protective agent disclosed herein is produced by a method including a step (A) of dissolving a material cellulose derivative in a solvent to prepare a material cellulose derivative solution. As used herein, “dissolve” represents dissolving or dispersing. Furthermore, “dissolving” preferably results in a state of dissolving at least a part; a part of the residual may be dispersed in a solvent, and particularly preferably, is completely dissolved.

A method of dissolving a material cellulose derivative in a solvent is not particularly limited, and is preferably a method of adding a material cellulose derivative to a solvent and stirring together. A stirring method is not particularly limited, and a known method can be appropriately used. Stirring time is not particularly limited.

The material cellulose derivative solution may also contain a basic compound. As used herein, a basic compound refers to a compound having a function to be dissolved in water to rise the pH of an aqueous solution. Available examples of the basic compound include organic or inorganic nitrogen-containing basic compounds, hydroxides of alkali metals, hydroxides of alkaline earth metals, quaternary phosphonium compounds, and various carbonate salts or hydrogen carbonate salts. Examples of the nitrogen-containing basic compounds include quaternary ammonium compounds, ammonia, amines (preferably, water-soluble amines). Such a basic compound can be used singly or in combination of two or more kinds thereof.

Among these basic compounds, at least one kind of basic compound selected from e.g., alkali metal hydroxides, quaternary ammonium hydroxides, or ammonia can be preferably used. Among them, potassium hydroxide, tetraalkyl ammonium hydroxide (e.g., tetramethylammonium hydroxide) and ammonia are more preferably used, with ammonia being especially suitable.

The content of a basic compound in the material cellulose derivative solution is not particularly limited, and is preferably 0.0001% by weight or more, more preferably 0.001% by weight or more, even more preferably 0.01% by weight or more. The content of a basic compound in the material cellulose derivative solution is not particularly limited, and is preferably 10% by weight or less, more preferably 1% by weight or less, even more preferably 0.1% by weight or less. The material cellulose derivative solution may contain no basic compound.

### <Step (B1) of Heating of Material Cellulose Derivative Solution>

In some embodiments, the polishing composition and/or substrate protective agent disclosed herein is produced by a method including a step (B1) of heating the material cellulose derivative solution and a step (B2) of adding a material surfactant to the material cellulose derivative solution that underwent the step (B1). In such an embodiment, the material cellulose derivative solution provided via the step (A) of preparing a material cellulose derivative solution is heat-treated at a selected heating temperature for a given duration of heating time in the step (B1). A method of heat treatment is not particularly limited, and a known method can be appropriately employed.

Heating temperature in the step (B1) is not particularly limited. In view of suitably solving entanglement of a material cellulose derivative, heating temperature in the step (B1) is usually, suitably 30° C. or higher, preferably 45° C. or higher, more preferably 50° C. or higher (e.g., 55° C. or higher), even more preferably 60° C. or higher. Further, heating temperature in the step (B1) should not be above the boiling point of the material cellulose derivative solution, is preferably 95° C. or lower, more preferably 75° C. or lower, and may be 70° C. or lower, 65° C. or lower, or 60° C. or lower.

Heating time in the step (B1) is not particularly limited. Heating time in the step (B1) designates time of retaining a material cellulose derivative solution at the heating temperature described above. In view of suitably solving entanglement of a material cellulose derivative, heating time in the step (B1) is suitably, approximately 20 seconds or more, preferably approximately 40 seconds or more (e.g., 1 minute or more). The upper limit of heating time in the step (B1) is not particularly limited. In view of efficient production, heating time in the step (B1) may be approximately 180 minutes or less, approximately 60 minutes or less, or approximately 30 minutes or less

<Step (B2) of Addition of Material Surfactant to Material Cellulose Derivative Solution that Underwent Heating>

To the material cellulose derivative solution heat-treated in the step (B1), a material surfactant is added in the step (B2). In addition of a material surfactant, the material cellulose derivative solution underwent the step (B1) may remain heated, or may have been once cooled. In other words, in some embodiments, a method of producing the polishing composition and/or substrate protective agent may include a step (B3) of cooling the material cellulose derivative solution thus heated between the step (B1) and the step (B2). In the cooling step (B3), a method of cooling the material cellulose derivative solution is not particularly limited, and may be, for example, allowing to cool. Further, cooling temperature is also not particularly limited. For example, the material cellulose derivative solution may be cooled to room temperature. In view of solving entanglement of a material cellulose derivative, the material cellulose derivative solution that underwent the step (B1) has been preferably in a heated state in addition of a material surfactant in the step (B2), in a method of producing the polishing composition and/or substrate protective agent disclosed herein.

In the step (B2), in addition of a material surfactant, the surfactant may be heated at a raised temperature higher than room temperature, or may not be heated. A material surfactant heated to an appropriate temperature tends to homogeneously disperse in a liquid, and facilitate exertion of a function as a surfactant. In view of further improving an effect of addition of a material surfactant and in view of reducing lowering of temperature of a material cellulose derivative solution that underwent the step (B1), it is preferable that a material surfactant to be added in the step (B2) be heated to a temperature higher than room temperature. Temperature of a material surfactant to be added in the step (B2) can be selected corresponding to the kind of the material surfactant, and is, in some embodiments, 30° C. or higher, preferably 35° C. or higher, more preferably 40° C. or higher. Temperature of a material surfactant to be added in the step (B2) is usually, suitably 75° C. or lower, preferably 65° C. or lower (e.g., 60° C. or lower), and may be 55° C. or lower, 50° C. or lower, or 45° C. or lower.

In some embodiments, a material surfactant is added in a solution form to the material cellulose derivative solution that underwent the step (B1). In such an embodiment, the content of a material surfactant in the material surfactant solution is not particularly limited. In view of handling, the content of a material surfactant in the material surfactant solution can be, e.g., 0.01 to 100% by weight, preferably 0.1 to 95% by weight, more preferably 1 to 90% by weight.

In the mixture liquid of a material cellulose derivative and a surfactant provided via the step (B2), the content of the material cellulose derivative is not particularly limited. The content of the material cellulose derivative in the mixture liquid can be, e.g., 0.1% by weight or more, and is preferably 0.5% by weight or more, more preferably 1.0% by weight or more. In view of filterability, the content of the material cellulose derivative in the mixture liquid is preferably 5% by weight or less, more preferably 4% by weight or less, even more preferably 3% by weight or less.

In the mixture liquid of a material cellulose derivative and a surfactant provided via the step (B2), the content of the material surfactant is not particularly limited. The content of a material surfactant in the mixture liquid can be, e.g., 0.005% by weight or more, and is, in view of substrate protectivity, preferably 0.01% by weight or more, more preferably 0.03% by weight or more. The content of a material surfactant in the mixture liquid is preferably 1% by weight or less, more preferably 0.75% by weight or less, even more preferably 0.5% by weight or less.

In the mixture liquid of a material cellulose derivative and a surfactant provided via the step (B2), the ratio of the content of the material cellulose derivative to the content of the material surfactant is not particularly limited. In view of substrate protectivity, the content ratio is preferably 3.0 or more, more preferably 5.0 or more, even more preferably 10 or more, and may be 12 or more, or 15 or more, on a weight basis. The content ratio is, e.g., 100 or less, preferably 50 or less, more preferably 30 or less, even more preferably 25 or less, and may be 20 or less, on a weight basis.

The mixture liquid of a cellulose derivative and a surfactant prepared via the step (B2) may be directly used as the substrate protective agent. Alternatively, the substrate protective agent may be produced via further treatment, such as dilution, concentration, pH adjustment, or filtration, after the step (B2).

### <Step (C1) of Addition of Material Surfactant to Material Cellulose Derivative Solution>

In some embodiments, the polishing composition and substrate protective agent disclosed herein are produced by a method including a step (C1) of adding a material surfactant to the material cellulose derivative solution to prepare an additive mixture liquid and a step (C2) of heating the additive mixture liquid.

In the step (C1), in addition of a material surfactant, the material surfactant may be heated at a raised temperature higher than room temperature, or may not be heated. A material surfactant heated to a suitable temperature tends to homogeneously disperse in a liquid, and facilitate exertion of a function as a surfactant. In view of further improving an effect of addition of a surfactant, a material surfactant to be added in the step (C1) is preferably heated to a temperature higher than room temperature. Temperature of a material surfactant to be added in the step (C1) can be selected corresponding to the kind of the surfactant, and is, in some embodiments, 30° C. or higher, preferably 35° C. or higher, more preferably 40° C. or higher. Temperature of a surfactant to be added in the step (C1) is usually, suitably 75° C. or lower, preferably 65° C. or lower (e.g., 60° C. or lower), and may be 55° C. or lower, 50° C. or lower, or 45° C. or lower.

In some embodiments, a material surfactant is added in a solution form to a material cellulose derivative solution. In such an embodiment, the content of a material surfactant in the material surfactant solution is not particularly limited. In view of handling, the content of a material surfactant in the material surfactant solution can be, e.g., 0.01 to 100% by weight, preferably 0.1 to 95% by weight, more preferably 1 to 90% by weight.

In the additive mixture liquid prepared in the step (C1), the content of a material cellulose derivative is not particularly limited. The content of a material cellulose derivative in the additive mixture liquid can be, e.g., 0.1% by weight or more, and is preferably 0.5% by weight or more, more preferably 1.0% by weight or more. In view of filterability, the content of a material cellulose derivative in the additive mixture liquid is preferably 5% by weight or less, more preferably 4% by weight or less, even more preferably 3% by weight or less.

In the additive mixture liquid prepared in the step (C1), the content of a material surfactant is not particularly limited. The content of a material surfactant in the additive mixture liquid can be, e.g., 0.005% by weight or more, and is preferably 0.01% by weight or more, more preferably 0.03% by weight or more. In view of filterability, the content of a material surfactant in the additive mixture liquid is preferably 1% by weight or less, more preferably 0.5% by weight or less (e.g., 0.25% by weight or less), even more preferably 0.1% by weight or less.

In the additive mixture liquid prepared in the step (C1), the ratio of the content of a material cellulose derivative to the content of a material surfactant is not particularly limited. In view of substrate protectivity, the content ratio is preferably 3.0 or more, more preferably 5.0 or more, even more preferably 10 or more, and may be 12 or more, or 15 or more, on a weight basis. The content ratio is, e.g., 100 or less, preferably 50 or less, more preferably 30 or less, even more preferably 25 or less, and may be 20 or less, on a weight basis.

### <Step (C2) of Heating of Additive Mixture Liquid>

The additive mixture liquid prepared by the step (C1) is heat-treated at a selected heating temperature for a given duration of heating time in the step (C2). A method of heat treatment is not particularly limited, and a known method can be appropriately employed.

Heating temperature in the step (C2) is not particularly limited. In view of suitably solving entanglement of a material cellulose derivative, heating temperature in the step (C2) is usually, suitably 30° C. or higher, preferably 45° C. or higher, more preferably 50° C. or higher (e.g., 55° C. or higher), even more preferably 60° C. or higher. Further, heating temperature in the step (C2) should not be above the boiling point of the additive mixture liquid, is preferably 95° C. or lower, more preferably 75° C. or lower, and may be 70° C. or lower, 65° C. or lower, or 60° C. or lower.

Heating time in the step (C2) is also not particularly limited. Heating time designates time of retaining an additive mixture liquid to the heating temperature described above. In view of suitably solving entanglement of a material cellulose derivative, heating time in the step (C2) is suitably, approximately 20 seconds or more, preferably approximately 40 seconds or more (e.g., 1 minute or more). The upper limit of heating time in the step (C2) is not particularly limited. In view of efficient production, heating time in the step (C2) may be approximately 180 minutes or less, approximately 60 minutes or less, or approximately 30 minutes or less.

The mixture liquid of a cellulose derivative and a surfactant provided via the step (C2) may be directly used as a substrate protective agent. Alternatively, the substrate protective agent may be produced via further treatment, such as dilution, concentration, pH adjustment, or filtration, after the step (C2)

### <Step (D) of Mixing Substrate Protective Agent, Abrasive, and Basic Compound>

The polishing composition disclosed herein contains a substrate protective agent prepared by any method disclosed herein. In some embodiments, a method of producing the polishing composition disclosed herein further includes a step (D) of mixing the substrate protective agent, an abrasive, and a basic compound.

A mixing method, a mixing condition, and the like of each kind of component in the mixing step (D) are not particularly limited. For example, another component may be added to a substrate protective agent prepared by any method disclosed herein, or the polishing additive described above may be added to another component. The order of adding each kind of component is also not particularly limited, and these may be added simultaneously or serially, or only some components may be added simultaneously. A mixing device is also not particularly limited. For example, a well-known mixing device such as a blade stirrer, an ultrasonic disperser, or a homomixer can be used.

Hereinafter, description will be made for components contained in a polishing composition and/or substrate protective agent in some embodiments.

### (Abrasive)

The polishing composition disclosed herein contains an abrasive. The abrasive functions to mechanically polish a surface of an object to be polished. The material quality, shape, etc., of the abrasive are not particularly limited, and can be appropriately selected corresponding to a purpose of use, an aspect of use, etc. of the polishing composition. Examples of the abrasive include inorganic particles, organic particles, and organic-inorganic composite particles. Specific examples of the inorganic particles include oxide particles such as silica particles, alumina particles, cerium oxide particles, chromium oxide particles, titanium dioxide particles, zirconium oxide particles, magnesium oxide particles, manganese dioxide particles, zinc oxide particles, and red iron oxide particles; nitride particles such as silicon nitride particles and boron nitride particles; carbide particles such as silicon carbide particles and boron carbide particles; diamond particles; and carbonates such as calcium carbonate and barium carbonate. Specific examples of the organic particles include polymethylmethacrylate (PMMA) particles, poly(meth)acrylic acid particles ((meth)acrylic acid in this context is intended to refer inclusively to acrylic acid and methacrylic acid), and polyacrylonitrile particles. Such an abrasive can be used singly or in combination of two or more kinds thereof.

The abrasive is preferably inorganic particles, more preferably particles formed of metal or semimetal oxide, and silica particles are especially suitable. When the polishing composition is used in polishing (e.g., final polishing) an object to be polished having a surface formed of silicon, such as a silicon wafer as described later, it is particularly beneficial to employ silica particles as an abrasive.

Specific examples of the silica particles include colloidal silica, fumed silica, and precipitated silica. The silica particles can be used singly or in combination of two or more kinds thereof. Colloidal silica is particularly preferably used because it facilitates production of a polishing surface with an excellent surface grade after polishing. Examples of colloidal silica to be potentially preferably employed include colloidal silica prepared from water glass (sodium silicate) as a raw material by ion-exchanging, and colloidal silica prepared from alkoxide (colloidal silica produced by a hydrolysis-condensation reaction of alkoxysilane). Colloidal silica can be used singly or in combination of two or more kinds thereof.

The absolute specific gravity of silica that forms the silica particles is preferably 1.5 or more, more preferably 1.6 or more, even more preferably 1.7 or more. The upper limit of the absolute specific gravity of silica is not particularly limited, and is typically 2.3 or less, e.g., 2.2 or less. As the absolute specific gravity of the silica particles, a measured value derived by liquid replacement using ethanol as a replacing liquid can be employed.

The average primary particle diameter of the abrasive (typically, silica particles) is not particularly limited, and in view of a polishing removal rate, etc., it is preferably 5 nm or more, more preferably 10 nm or more. In view of providing a higher effect of polishing (an effect such as reduction in haze or removal of a defect), the average primary particle diameter is preferably 15 nm or more, more preferably 20 nm or more (e.g., more than 20 nm). In view of reducing a scratch, etc., the average primary particle diameter of the abrasive is preferably 100 nm or less, more preferably 50 nm or less, even more preferably 45 nm or less. In view of producing a lower-haze surface with ease, the average primary particle diameter of the abrasive in some embodiments may be 43 nm or less, less than 40 nm, or less than 38 nm.

An average primary particle diameter, as used herein, refers to a particle diameter (BET particle diameter) calculated from a specific surface area measured by a BET method (BET value) by the formula: average primary particle diameter (nm)=6000/(true density (g/cm³)×BET value (m²/g)). The specific surface area can be measured using e.g., a surface area measurement device with the product name of “Flow Sorb II 2300”, manufactured by Micromeritics Instrument Corporation.

The average secondary particle diameter of the abrasive (typically, silica particles) is not particularly limited, and can be appropriately selected from, e.g., the range of about 15 nm to 300 nm. In view of improving a polishing removal rate, the average secondary particle diameter is preferably 30 nm or more, more preferably 35 nm or more. In some embodiments, the average secondary particle diameter may be, e.g., 40 nm or more, 42 nm or more, or preferably 44 nm or more. The average secondary particle diameter is usually, generally 250 nm or less, preferably 200 nm or less, more preferably 150 nm or less. In some preferred embodiments, the average secondary particle diameter is 120 nm or less, more preferably 100 nm or less, even more preferably 70 nm or less.

An average secondary particle diameter, as used herein, refers to a particle diameter (volume average particle diameter) measured by dynamic light scattering. The average secondary particle diameter of the abrasive can be measured by dynamic light scattering using e.g., the product named “NANOTRAC UPA-UT151” manufactured by Nikkiso Co., Ltd.

The shape (outer shape) of the abrasive (typically, silica particles) may be globular or non-globular. Specific examples of the particles having non-globular forms include peanut-shaped (i.e., peanut shell-shaped) particles, cocoon-shaped particles, konpeito-shaped particles, and rugby ball-shaped particles. For example, the particles majorly including an abrasive (typically, silica particles) having a peanut shape or cocoon shape may be preferably employed.

Without particular limitation, the average value of major axis/minor axis ratios (average aspect ratio) of the abrasive (typically, silica particles) is theoretically 1.0 or more, preferably 1.05 or more, even more preferably 1.1 or more, and may be 1.2 or more. Increase in the average aspect ratio can achieve a higher polishing removal rate. In view of reducing scratches, etc., the average aspect ratio of the abrasive (typically, silica particles) is preferably 3.0 or less, more preferably 2.0 or less, even more preferably 1.5 or less, and may be 1.4 or less.

An exemplary specific procedure for acquiring the shape (outer shape) and the average aspect ratio of the abrasive (typically, silica particles) can be as follows: with use of a scanning electron microscope (SEM), collecting a predetermined number (e.g., 200) of the silica particles each independently having a discriminable shape; drawing a minimum rectangle circumscribed to an image of each of the collected particles; then calculating, as a major axis/minor axis ratio (aspect ratio), a value by dividing the long side length (major axis value) by the short side length (minor axis value) for the rectangle drawn for the image of each of the particles; and deriving the average aspect ratio from an arithmetic average of the aspect ratios for the predetermined number of the particles.

The polishing composition disclosed herein may contain an abrasive other than silica particles (hereinafter also referred to as “non-silica abrasive”), as far as an effect of the present invention is not significantly inhibited. Examples of the non-silica abrasive include inorganic particles, organic particles, and organic-inorganic composite particles. Specific examples of the inorganic particles include oxide particles such as alumina particles, cerium oxide particles, chromium oxide particles, titanium dioxide particles, zirconium oxide particles, magnesium oxide particles, manganese dioxide particles, zinc oxide particles, and red iron oxide particles; nitride particles such as silicon nitride particles and boron nitride particles; carbide particles such as silicon carbide particles and boron carbide particles; diamond particles; and carbonate salts such as calcium carbonate and barium carbonate. Specific examples of the organic particles include polymethylmethacrylate (PMMA) particles, poly(meth)acrylic acid particles ((meth)acrylic acid in this context is intended to refer inclusively to acrylic acid and methacrylic acid), and polyacrylonitrile particles. Such an abrasive can be used singly or in combination of two or more kinds thereof.

The art disclosed herein can be preferably performed in an embodiment where substantially only silica particles are used as an abrasive. In such a view, the proportion of silica particles in the total amount of an abrasive is suitably 90% by weight or more, preferably 95% by weight or more, more preferably 98% by weight or more (e.g., 99 to 100% by weight).

### (Basic Compound)

The polishing composition disclosed herein contains a basic compound. As used herein, a basic compound refers to a compound having a function to be dissolved in water to rise the pH of an aqueous solution. Use of a basic compound facilitates improvement in solubility of a water-soluble polymer in a liquid to be filtrated. Available examples of the basic compound include organic or inorganic nitrogen-containing basic compounds, hydroxides of alkali metals, hydroxides of alkaline earth metals, quaternary phosphonium compounds, and various carbonate salts or hydrogen carbonate salts. Examples of the nitrogen-containing basic compounds include quaternary ammonium compounds, ammonia, amines (preferably, water-soluble amines). Such a basic compound can be used singly or in combination of two or more kinds thereof.

Among these basic compounds, at least one kind of basic compound selected from e.g., alkali metal hydroxides, quaternary ammonium hydroxides, or ammonia can be preferably used. Among them, potassium hydroxide, tetraalkyl ammonium hydroxide (e.g., tetramethylammonium hydroxide) and ammonia are more preferably used, with ammonia being especially suitable.

### (Water)

The polishing composition disclosed herein typically contains water. Examples of water in the polishing composition to be potentially preferably used include ion-exchanged water (deionized water), pure water, ultrapure water, and distilled water. In water to be used, the content of transition metal ions is preferably, e.g., 100 ppb or less in total, in order to avoid inhibiting a function of another component in the polishing composition as much as possible. For example, water can have improved purity by removal of impurity ions by ion-exchange resin, removal of contaminants by a filter, distillation, etc. The polishing composition disclosed herein may further contain an organic solvent that can be uniformly mixed with water (lower alcohol, lower ketone, etc.), as appropriate. In a solvent(s) in the polishing composition, water preferably accounts for 90% by volume or more, more preferably 95% by volume or more (e.g., 99 to 100% by volume).

### (Water-Soluble Polymer)

The polishing composition disclosed herein contains a cellulose derivative as a water-soluble polymer. The cellulose derivative can be contained in a substrate protective agent to be prepared by any method disclosed herein. The kind and weight-average molecular weight (Mw) of the cellulose derivative in the polishing composition is not particularly limited and can be suitably selected from a range as the same as that of the kind and weight-average molecular weight (Mw) of the aforementioned material cellulose derivative. The cellulose derivative can be used singly or in combination of two or more kinds thereof.

The polishing composition and/or substrate protective agent disclosed herein may contain an optional water-soluble polymer other than cellulose derivatives, as far as an effect of the present invention is not significantly inhibited. The kind of the optional water-soluble polymer is not particularly limited, and a substance having at least one functional group selected from cation groups, anion groups, or nonion groups can be used. The optional water-soluble polymer can have a hydroxy group, a carboxy group, an acyl group, an acyloxy group, a sulfo group, an amide group, a quaternized ammonium structure, a heterocycle structure, a vinyl structure, a polyoxyalkylene structure, or the like.

Examples of the optional water-soluble polymer include starch derivatives; polymers containing an oxyalkylene unit such as copolymers of ethylene oxide (EO) and propylene oxide (PO); vinyl alcohol-based polymers such as polyvinyl alcohol (PVA); nitrogen atom-containing polymers such as polymers containing an N-vinyl type monomer unit, imine derivatives, and polymers containing an N-(meth)acryloyl type monomer unit. In view of use for the polishing composition to potentially improve polishing performance, the optional water-soluble polymer is preferably a vinyl alcohol-based polymer or a polymer containing a N-(meth)acryloyl type monomer unit. The optional water-soluble polymer can be used singly or in combination of two or more kinds thereof. In view of providing more simple composition, the polishing composition and/or substrate protective agent disclosed herein may not contain any optional water-soluble polymer other than cellulose derivatives.

### (Surfactant)

The polishing composition disclosed herein contains a surfactant. The surfactant may be contained in a substrate protective agent to be prepared by any method disclosed herein. The kind and weight-average molecular weight (Mw) of a surfactant in the polishing composition is not particularly limited and can be suitably selected from a range as the same as that of the kind and weight-average molecular weight (Mw) of a material surfactant as described above. The surfactant can be used singly or in combination of two or more kinds thereof.

### (Other Components)

The polishing composition disclosed herein may further contain, as appropriate, a known additive that can be used for a polishing composition (e.g., a polishing composition used for a final polishing step of a silicon wafer), such as organic acid, an organic acid salt, an inorganic acid, an inorganic acid salt, a chelating agent, an antiseptic agent, or an antifungal agent, as far as an effect of the present invention is not significantly inhibited.

The organic acid and salts thereof, and inorganic acid and salts thereof can be used singly or in combination of two or more kinds thereof. Examples of the organic acid include aliphatic acids such as formic acid, acetic acid, and propionic acid; aromatic carboxylic acids such as benzoic acid and phthalic acid; itaconic acid; citric acid; oxalic acid; tartaric acid; malic acid; maleic acid; fumaric acid; succinic acid; glycolic acid; malonic acid; gluconic acid; alanine; glycine; lactic acid; hydroxyethylidene diphosphoric acid (HEDP); organic sulfonic acid such as methanesulfonic acid; nitrilotris(methylenephosphoric acid) (NTMP); and organic phosphonic acid such as phosphonobutane tricarboxylic acid (PBTC). Examples of the organic acid salt include alkali metal salts (sodium salts, potassium salts, lithium salts, etc.) and ammonium salts of organic acid. Examples of the inorganic acid include hydrochloric acid, phosphoric acid, sulfuric acid, phosphonic acid, nitric acid, phosphinic acid, boric acid, and carbonic acid. Examples of the inorganic acid salt include alkali metal salts (sodium salts, potassium salts, lithium salts, etc.) of inorganic acid.

The chelating agent can be used singly or in combination of two or more kinds thereof. Examples of the chelating agent include aminocarboxylic acid-based chelating agents and organic phosphonic acid-based chelating agents. Preferred examples of the chelating agents include ethylenediamine tetrakis(methylenephosphinic acid), diethylene triamine penta(methylenephosphinic acid), and diethylene triamine pentaacetic acid. Examples of the antiseptic agent and antifungal agent include isothiazoline-based compounds, paraoxybenzoic acid esters, and phenoxyethanol.

The polishing composition disclosed herein preferably contains substantially no oxidant. This is because when the polishing composition contains an oxidant, supply of the polishing composition to a substrate (e.g., a silicon wafer) can cause oxidation on a surface of the substrate and generate an oxide layer, thereby reducing a polishing removal rate. Specific examples of an oxidant in this context include hydrogen peroxide (H₂O₂), sodium persulfate, ammonium persulfate, and sodium dichroloisocyanurate. The phrase that the polishing composition contains substantially no oxidant means not containing an oxidant at least intentionally. Accordingly, when inevitably containing a small amount of an oxidant (e.g., the molar concentration of an oxidant in the polishing composition is 0.001 mole/L or less, preferably 0.0005 mole/L or less, more preferably 0.0001 mole/L or less, even more 0.00005 mole/L or less, particularly preferably 0.00001 mole/L or less) derived from a raw material, a production method, etc., the polishing composition can be encompassed within the concept of a polishing composition containing substantially no oxidant in this context.

<pH>

The pH of the polishing composition disclosed herein is not particularly limited, and suitable pH can be employed corresponding to a substrate, etc. In some embodiments, the pH of the polishing composition is suitably 8.0 or more, preferably 8.5 or more, more preferably 9.0 or more. Higher pH of the polishing composition tends to lead to increase in a polishing removal rate. Meanwhile, in view of reducing dissolution of silica particles and mitigating reduction in action of mechanical polishing, the pH of the polishing composition is usually, generally 12.0 or less, preferably 11.0 or less, more preferably 10.8 or less, even more preferably 10.5 or less.

In the art disclosed herein, the pH of the polishing composition can be known by performing three-point calibration with standard buffers (a phthalate pH buffer with pH 4.01 (25° C.), a neutral phosphate pH buffer with pH 6.86 (25° C.), and a carbonate pH buffer with pH 10.01 (25° C.)) using a pH meter (e.g., a glass-electrode hydrogen ion concentration indicator (model: F-72) manufactured by Horiba, Ltd.), and then inserting a glass electrode into a composition to be measured, leaving it to stand for 2 minutes or more until stabilization and conducting measurement.

### <Substrate Protective Agent>

The substrate protective agent disclosed herein refers to a group of substances capable of being absorbed onto at least a surface of a substrate to be polished and adjusting its polishing performance in polishing with use of a polishing composition, and particularly contains a cellulose derivative and a surfactant. The cellulose derivative in the substrate protective agent tends to have associates with a reduced size and/or amount and improved dispersibility as compared to a material cellulose derivative. Therefore, the substrate protective agent is likely to have high light transmittance. Without particular limitation, visible light transmittance of the substrate protective agent disclosed herein is preferably 85% or more, more preferably 90% or more (e.g., 92% or more), even more preferably 95% or more (e.g., 98% or more). The upper limit of visible light transmittance of the substrate protective agent is not particularly limited. Theoretically, visible light transmittance of the substrate protective agent is 100% or less, and may be 99% or less. The visible light transmittance described above is an average visible light transmittance in a wavelength range of 380 to 780 nm.

The content of a cellulose derivative in the substrate protective agent disclosed herein is not particularly limited. The content of a cellulose derivative in the substrate protective agent can be, e.g., 0.0001% by weight or more, is preferably 0.0005% by weight or more, more preferably 0.001% by weight or more, even more preferably 0.003% by weight or more, and may be 0.005% by weight or more, 0.01% by weight or more, 0.05% by weight or more, 0.1% by weight or more, 0.5% by weight or more, or 1.0% by weight or more. The content of a cellulose derivative in the substrate protective agent is preferably 5% by weight or less, more preferably 4% by weight or less, even more preferably 3% by weight or less, and may be 1% by weight or less, 0.5% by weight or less, 0.1% by weight or less, 0.05% by weight or less, 0.01% by weight or less, or 0.008% by weight or less.

The content of a surfactant in the substrate protective agent is not particularly limited. The content of a surfactant in the substrate protective agent can be, e.g., 0.00005% by weight or more, preferably 0.0001% by weight or more, more preferably 0.0003% by weight or more, even more preferably 0.0005% by weight or more, and may be 0.0008% by weight or more, 0.001% by weight or more, 0.005% by weight or more, 0.01% by weight or more, or 0.03% by weight or more. The content of a surfactant in the substrate protective agent is preferably 1% by weight or less, more preferably 0.5% by weight or less (e.g., 0.25% by weight or less), even more preferably 0.1% by weight or less, and may be 0.05% by weight or less, 0.03% by weight or less, 0.01% by weight or less, 0.005% by weight or less, or 0.003% by weight or less.

### <Polishing Slurry>

The polishing composition disclosed herein is typically supplied onto a surface of a substrate in form of a polishing slurry containing the polishing composition, and used for polishing the substrate. The polishing slurry can be, e.g., prepared by diluting any of the polishing compositions disclosed herein (typically, diluting with water). Alternatively, the polishing composition may be used directly as the polishing slurry. Other examples of the polishing slurry containing the polishing composition disclosed herein include a polishing slurry formed by adjusting the pH of the composition.

The content of an abrasive (typically, silica particles) in the polishing slurry is not particularly limited, and is, e.g., 0.001% by weight or more, preferably 0.05% by weight or more, more preferably 0.10% by weight or more. Increase in the content of an abrasive can provide a higher polishing removal rate. The content is suitably 10% by weight or less, preferably 7% by weight or less, more preferably 5% by weight or less, even more preferably 2% by weight or less, and may be, e.g., 1% by weight or less, 0.75% by weight or less, or 0.5% by weight or less. This facilitates achieving maintenance of a surface quality.

The content of a basic compound in the polishing slurry is not particularly limited. In view of improving a polishing removal rate, the content is usually, suitably 0.0005% by weight or more, preferably 0.001% by weight or more, more preferably 0.003% by weight or more. In view of improving a surface quality (e.g., reduction in haze), etc., the content is suitably less than 0.1% by weight, preferably less than 0.05% by weight, more preferably less than 0.03% by weight (e.g., less than 0.025% by weight, and further, less than 0.01% by weight).

The content of a cellulose derivative in the polishing slurry is not particularly limited, and can be, e.g., 0.0001% by weight or more. In view of reducing haze, etc., the content is preferably 0.0005% by weight or more, more preferably 0.001% by weight or more, even more preferably 0.002% by weight or more, e.g., 0.005% by weight or more. In view of polishing removal rate, etc., the content is preferably 0.2% by weight or less, more preferably 0.1% by weight or less, even more preferably 0.05% by weight or less (e.g., 0.02% by weight or less, and further 0.015% by weight or less).

When the polishing slurry contains any water-soluble polymer other than cellulose derivatives, the content of the water-soluble polymer in the polishing slurry is not particularly limited, and can be, e.g., 0.0001% by weight or more. In view of reducing haze, etc., the content is preferably 0.0005% by weight or more, more preferably 0.001% by weight or more, even more preferably 0.002% by weight or more, e.g., 0.005% by weight or more. In view of polishing removal rate, etc., the content is preferably 0.2% by weight or less, more preferably 0.1% by weight or less, even more preferably 0.05% by weight or less (e.g., 0.02% by weight or less, and further 0.015% by weight or less).

The content of a surfactant in the polishing slurry is not particularly limited. Usually, the content of the surfactant can be 0.00001% by weight or more in view of improvement in dispersibility of a cellulose derivative, cleanability, etc. In view of reduction in haze, etc., the content is preferably 0.0002% by weight or more, more preferably 0.0003% by weight or more, even more preferably 0.0005% by weight or more. In view of a polishing removal rate, etc., the content preferably 0.1% by weight or less, more preferably 0.01% by weight or less, even more preferably 0.005% by weight or less (e.g., 0.002% by weight or less).

### <Concentrate>

The polishing composition disclosed herein may be a concentrated form (i.e., a concentrate form of a polishing slurry) before supply to a substrate. Such a concentrated form of the polishing composition is beneficial in view of convenience, cost reduction, etc. in production, distribution, storage, etc. The concentration factor is not particularly limited, can be, e.g., about 2-fold to 100-fold in volume, and is usually suitably about 5-fold to 50-fold (e.g., about 10-fold to 40-fold). Such a concentrate can be diluted at a desired timing to prepare a polishing slurry (a working slurry), and can be used in an embodiment of supplying the polishing slurry to a substrate. The dilution can be performed, e.g., by adding water to the concentrate and mixing them.

When the polishing composition (i.e., a concentrate) is diluted and used for polishing, the content of an abrasive in the concentrate can be, e.g., 25% by weight or less. In view of dispersion stability, filterability, etc. of the polishing composition, the content is usually, preferably 20% by weight or less, more preferably 15% by weight or less. In some preferred embodiments, the content of an abrasive may be 10% by weight or less, or 5% by weight or less. In view of convenience and cost reduction, etc. in production, distribution, storage, etc., the content of an abrasive in the concentrate can be, e.g., 0.1% by weight or more, and is preferably 0.5% by weight or more, more preferably 0.7% by weight or more, even more preferably 1% by weight or more.

In some embodiments, the content of a basic compound in the concentrate can be, e.g., less than 15% by weight. In view of storage stability, etc., the content is usually, preferably 0.7% by weight or less, more preferably 0.4% by weight or less. In view of convenience, cost reduction, etc. in production, distribution, storage, etc., the content of a basic compound in the concentrate can also be, e.g., 0.005% by weight or more, preferably 0.01% by weight or more, more preferably 0.02% by weight or more, even more preferably 0.05% by weight or more.

In some embodiments, the total content of a cellulose derivative in the concentrate can be, e.g., 3% by weight or less. In view of filterability, cleanability, and the like of the polishing composition, the content is usually, preferably 1% by weight or less, more preferably 0.5% by weight or less. In view of convenience, cost reduction, etc. in production, distribution, storage, etc., the content is also usually, suitably 0.001% by weight or more, preferably 0.005% by weight or more, more preferably 0.01% by weight or more.

In some embodiments, the content of a surfactant in the concentrate can be, e.g., 0.25% by weight or less, preferably 0.15% by weight or less, more preferably 0.1% by weight or less, and may be 0.05% by weight or less, or 0.025% by weight or less. The content of a surfactant in the concentrate can also be, e.g., 0.0001% by weight or more, and is preferably 0.001% by weight or more, more preferably 0.005% by weight or more, even more preferably 0.01% by weight or more.

### <Application>

The polishing composition and/or substrate protective agent disclosed herein can be applied to polishing of substrates with various material qualities and shapes. Examples of materials of the substrates include metals or semimetals such as silicon materials, aluminum, nickel, tungsten, copper, tantalum, titanium, and stainless steel, or alloys thereof, glassy substances such as quartz glass, aluminosilicate glass, and glassy carbon; ceramic materials such as alumina, silica, sapphire, silicon nitride, tantalum nitride, and titanium carbide; compound semiconductor substrate materials such as silicon carbide, gallium nitride, and gallium arsenide; and resin materials such as polyimide resins. Among these, a plurality of materials may form a substrate. The shape of a substrate is not particularly limited. The polishing composition disclosed herein can be applied to polishing of a substrate having a plane that has, e.g., a plate shape or a polyhedron shape, or polishing of an end of a substrate (e.g., polishing of a wafer edge). The substrate protective agent disclosed herein may also be applied to rinsing of the substrate in some embodiments.

The polishing composition and/or substrate protective agent disclosed herein can be particularly preferably used for polishing of a surface formed of a silicon material (typically, polishing of a silicon wafer). Specific examples of the silicon material include silicon single crystal, amorphous silicon, and polysilicon. The polishing composition disclosed herein can be particularly preferably used for polishing of a surface formed of silicon single crystal (e.g., polishing of a silicon wafer). The substrate protective agent disclosed herein may also be applied to rinsing of the substrate in some embodiments.

The polishing composition and/or substrate protective agent disclosed herein can be preferably applied to a polishing step of a substrate (e.g., a silicon wafer). The substrate may be subjected to common treatment that can be applied to a substrate in a step upstream of a polishing step, such as lapping or etching, before a polishing step with the polishing composition disclosed herein.

The polishing composition and/or substrate protective agent disclosed herein is effective for use in a final step or an immediately preceding polishing step of a substrate (e.g., a silicon wafer), and use in a final polishing step is especially advantageous. The final polishing step in this context refers to a last polishing step (i.e., a step preceding no further polishing) in a production process of an object. The polishing composition disclosed herein may also be used for a polishing step at the upstream relative to a final polishing (that refers to a stock polishing step between a rough polishing step and a final polishing step, typically includes at least a primary polishing step, and may further include a secondary, tertiary or more-order polishing step(s)), e.g., a polishing step performed just before final polishing.

The polishing composition and/or substrate protective agent disclosed herein is effective in application to polishing (typically, final polishing or the preceding polishing thereof) of e.g., a silicon wafer prepared to have a surface with a surface roughness of 0.01 nm to 100 nm through an upstream step. Application to final polishing is especially advantageous. The surface roughness Ra of a substrate can be measured using e.g., the laser scanning surface roughness meter “TMS-3000WRC” manufactured by Schmitt Measurement System Inc.

The polishing composition used in the art disclosed herein may be a single-agent type or a multi-agent type such as a two-agent type. For example, the composition may be configured to prepare a polishing slurry by mixing of Part A, which contains at least an abrasive among components of the polishing composition, and Part B, which contains at least a part of the remaining components, and mixing and diluting them at an appropriate timing, as appropriate. Part B may be any substrate protective agent disclosed herein. Part A may experience filtration once or twice or more times.

### <Polishing>

The polishing composition and/or substrate protective agent disclosed herein can be used for polishing of a substrate e.g., in an embodiment including the following operation. Description will now be made for a preferred embodiment of a method of polishing a silicon wafer as a substrate with use of the polishing composition disclosed herein.

In other words, a polishing slurry containing any of the polishing compositions or substrate protective agent disclosed herein is provided. Provision of the polishing slurry may contain subjecting the polishing composition to operation such as concentration adjustment (e.g., dilution), pH adjustment, etc., thereby preparing the polishing slurry. Alternatively, the polishing composition may be directly used as a polishing slurry.

Then, the polishing slurry is supplied to a substrate, and polishing is carried out by a common method. For example, in final polishing of a silicon wafer, typically, a silicon wafer that underwent a lapping step is set in a typical polishing machine, and then the polishing slurry is supplied via a polishing pad of the polishing machine onto a surface to be polished in the silicon wafer. Typically, while the polishing slurry is consecutively supplied, a polishing pad is pushed against a surface to be polished of a silicon wafer and both are relatively moved (e.g., rotatably moved). Through such a polishing step, polishing of a substrate is completed.

A polishing pad used in the polishing step is not particularly limited. For example, polishing pads such as a foamed polyurethane type, a non-woven fabric type, and a suede type can be used. Each polishing pad may or may not contain an abrasive. Usually, a polishing pad containing no abrasive is preferably used.

A substrate polished by using the polishing composition disclosed herein is typically cleaned. Cleaning can be performed using a suitable cleaning liquid. A cleaning liquid to be used herein is not particularly limited. For example, SC-1 cleaning liquid (a mixture solution of ammonium hydroxide (NH₄OH), hydrogen peroxide (H₂O₂), and water (H₂O)), SC-2 cleaning liquid (a mixture solution of HCl, H₂O₂, and H₂O), an ozone water cleaning liquid, a hydrofluoric acid cleaning liquid, etc., which are common in the art of semiconductors or the like, can be used. For example, temperature of a cleaning liquid can be within the range of room temperature (typically, about 15° C. to 25° C.) or higher to about 90° C. In view of improving an effect of cleaning, a cleaning liquid at 50° C. to 85° C. can be preferably used.

As mentioned above, the art disclosed herein may include providing a method of producing a polished material including a polishing step by any of the aforementioned polishing methods (e.g., a method of producing a silicon wafer) and a polished material (e.g., a silicon wafer) produced by the method.

The items disclosed herein include the followings.
[1] A method of producing a polishing composition containing an abrasive, a basic compound, a cellulose derivative, and a surfactant, the method including:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.
[2] The method of producing a polishing composition according to [1] above, wherein the material surfactant is added at a raised temperature higher than room temperature in the step (B2) or the step (C1).
[3] A method of producing a substrate protective agent containing a cellulose derivative and a surfactant, the method including:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.
[4] A substrate protective agent containing a cellulose derivative and a surfactant, the method including:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.
[5] A polishing composition containing an abrasive, a basic compound, and a substrate protective agent,
wherein the substrate protective agent contains a cellulose derivative and a surfactant, and
wherein the substrate protective agent is prepared by a method including:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.
[6] The polishing composition according to [5] above, used for polishing a surface formed of a silicon material.
[7] A concentrate of the polishing composition according to [5] or [6] above.
[8] A polishing method including a step of polishing a surface formed of a silicon material with use of the polishing composition according to any of [5] to [7] above.
[9] A polishing composition containing an abrasive, a basic compound, and a substrate protective agent,
wherein the substrate protective agent contains a cellulose derivative, and a surfactant, and
wherein the substrate protective agent has a visible light transmittance of 85% or more.

### EXAMPLES

Several examples relating to the present invention will be described below, but the present invention is not intended to be limited to the embodiments shown in the examples. In the following description, “part” and “%” are on a weight basis unless otherwise specified.

### Testing Example 1

### <Preparation of Substrate Protective Agent>

### Example 1

### [Dissolution of Material HEC]

At room temperature, deionized water (DIW) was charged in a glass beaker, and a powder of material hydroxyethyl cellulose (hereinafter also referred to as “material HEC”) with a weight-average molecular weight (Mw) of 280,000 was charged and dissolved while being stirred. Subsequently, ammonia water is added, thereby preparing a material hydroxyethyl cellulose aqueous solution containing material HEC (hereinafter also referred to as “material HEC aqueous solution”) with a concentration of 1.3% and ammonia with a concentration of 0.01%.

### [Heating of Material HEC Aqueous Solution]

Then 100 mL of the material HEC aqueous solution thus obtained was heated, and retained at 60° C. for 1 minute.

### [Addition of Material Surfactant]

To 100 mL of the material HEC aqueous solution thus heated, a material surfactant (1% aqueous solution) heated to and kept at 43° C. was charged and stirred, and then allowed to cool to room temperature, thereby providing a substrate protective agent according to this example containing hydroxyethyl cellulose with concentration of 1.2% and a material surfactant with a concentration of 0.067%. As a material surfactant, polyoxyethylene decyl ether with 5 moles ethylene oxide adduct (C10PEO5) having a weight-average molecular weight (Mw) of 378 was used.

### Examples 2 to 10

A substrate protective agent according to each of the examples was prepared in the same manner as in Example 1 except that heating temperature and heating time of a material HEC aqueous solution in the item “Heating of Material HEC Aqueous Solution” in Example 1 were changed as shown in Table 1.

### Example 11

According to the item “Heating of Material HEC Aqueous Solution” in Example 1, a material HEC aqueous solution was heated, and retained at 60° C. for 30 minutes. The substrate protective agent according to this example was prepared in the same manner as in Example 1, except that the material HEC aqueous solution was then allowed to cool to room temperature, followed by addition of a material surfactant (1% aqueous solution) heated to 43° C. to the material HEC aqueous solution kept at room temperature.

### Example 12

A material HEC aqueous solution was prepared in the same manner as in the item “Dissolution of Material HEC” in Example 1. A material surfactant (1% aqueous solution) heated to 43° C. was charged to the material HEC aqueous solution thus obtained and stirred, and the mixture liquid thus obtained was heated, and retained at 60° C. for 30 minutes. Subsequently, the heated mixture liquid was allowed to cool to room temperature, thereby providing a substrate protective agent according to this example containing hydroxyethyl cellulose with a concentration of 1.2% and a surfactant with a concentration of 0.067%. As a material surfactant, polyoxyethylene decyl ether with 5 moles ethylene oxide adduct (C10PEO5) having a weight-average molecular weight (Mw) of 378 was used as in Example 1.

### Example 13

The substrate protective agent according to this example was prepared in the same manner as in Example 1, except that heating time of the material HEC aqueous solution in the item “Heating of Material HEC aqueous solution” in Example 1 was changed to that as shown in Table 1, and that a material surfactant (1% aqueous solution) kept at room temperature (i.e., unheated) was charged in a heated material HEC aqueous solution in the item “Addition of Material Surfactant” in Example 1.

### Comparative Example 1

### [Heating of Material HEC Aqueous Solution]

At room temperature, deionized water (DIW) was charged in a glass beaker, and powder of a material hydroxyethyl cellulose (material HEC) with a weight-average molecular weight (Mw) of 280,000 was charged and dissolved while being stirred. Subsequently, ammonia water is added, thereby preparing a material HEC aqueous solution with a concentration of 1.3% and ammonia with a concentration of 0.01%.

### [Addition of Material Surfactant]

To 100 mL of the material HEC aqueous solution thus obtained (i.e., unheated material HEC aqueous solution), a material surfactant (1% aqueous solution) heated to 43° C. was charged and stirred, and then allowed to cool to room temperature, thereby providing a substrate protective agent according to this example containing hydroxyethyl cellulose with concentration of 1.2% and a material surfactant with a concentration of 0.067%. As a material surfactant, polyoxyethylene decyl ether with 5 moles ethylene oxide adduct (C10PEO5) having a weight-average molecular weight (Mw) of 378 was used, as in Example 1.

### Comparative Example 2

The substrate protective agent according to this example was prepared in the same manner as in Comparative Example 1, except that a material surfactant (1% aqueous solution) kept at room temperature (i.e., unheated) was charged to a material HEC aqueous solution (i.e., unheated material HEC aqueous solution) in the item “Addition of Material Surfactant” in Comparative Example 1.

### <Evaluation of Transmittance>

The average visible light transmittance of the substrate protective agent thus obtained according to each of the examples within a wavelength range of 380 to 780 nm was measured using a ultra-violet visible spectrophotometer (model “UV-2450”, manufactured by Shimadzu Corporation). The measurement was performed a day after preparation of a substrate protective agent according to each of the examples. Measurement conditions are shown as follows.

### [Measurement Conditions]

Concentration of measurement sample: 1.2% hydroxyethyl cellulose, 0.067% surfactant
Amount of measurement sample: 10 g
Temperature of measurement sample: room temperature
Scanning speed: medium speed
Sampling pitch: 1 nm
Slit width: 2 mm

The transmittance thus obtained is assessed according to the following three grades and shown in a corresponding column in Table 1:
95% or more of transmittance: E (excellent)
85% or more and less than 95% of transmittance: G (good)
less than 85% of transmittance: P (poor).

TABLE 1

| | Heat treatment | | | Temperature | Evaluation of |
|---|---|---|---|---|---|
| | | | Heating | of material | transmission of |
| | | Heating | time | surfactant in | substrate |
| | Object | temperature | [minutes] | addition | protective agent |
| Example 1 | material HEC | 60° C. | 1 | 43° C. | E |
| | aqueous solution | | | | |
| Example 2 | material HEC | 60° C. | 10 | 43° C. | E |
| | aqueous solution | | | | |
| Example 3 | material HEC | 60° C. | 30 | 43° C. | E |
| | aqueous solution | | | | |
| Example 4 | material HEC | 60° C. | 60 | 43° C. | E |
| | aqueous solution | | | | |
| Example 5 | material HEC | 60° C. | 180 | 43° C. | E |
| | aqueous solution | | | | |
| Example 6 | material HEC | 75° C. | 30 | 43° C. | E |
| | aqueous solution | | | | |
| Example 7 | material HEC | 75° C. | 180 | 43° C. | E |
| | aqueous solution | | | | |
| Example 8 | material HEC | 45° C. | 10 | 43° C. | G |
| | aqueous solution | | | | |
| Example 9 | material HEC | 45° C. | 30 | 43° C. | G |
| | aqueous solution | | | | |
| Example 10 | material HEC | 45° C. | 180 | 43° C. | G |
| | aqueous solution | | | | |
| Example 11 | material HEC | 60° C. | 30 | 43° C. | G |
| | aqueous solution | | | | |
| | (cooled after heat | | | | |
| | treatment) | | | | |
| Example 12 | mixture liquid of | 60° C. | 30 | 43° C. | E |
| | material HEC | | | | |
| | aqueous solution | | | | |
| | and | | | | |
| | material surfactant | | | | |
| Example 13 | material HEC | 60° C. | 30 | room | G |
| | aqueous solution | | | temperature | |
| Comparative | — | — | — | 43° C. | P |
| Example 1 | | | | | |
| Comparative | — | — | — | room | P |
| Example 2 | | | | temperature | |

As is clear from the results shown in Table 1, all of the substrate protective agents in Examples 1 to 10 and 13, which were prepared by adding a material surfactant to a heated material HEC aqueous solution, the substrate protective agent in Example 11, which was prepared by once cooling a heated material HEC aqueous solution to room temperature and adding a material surfactant, and the substrate protective agent in Example 12, which was prepared by mixing an unheated material HEC aqueous solution and a material surfactant and then heating the mixture liquid, were confirmed to have higher transmittance as compared to the substrate protective agents in Comparative Examples 1 and 2, which were prepared by mixing an unheated material HEC aqueous solution and a material surfactant. In particular, the substrate protective agents in Examples 1 to 7, which were prepared with setting a heating temperature of a material HEC aqueous solution to 60° C. or higher, exhibited better transmittance. The high transmittance is considered to be caused by reduction in the size or amount of HEC associates in the substrate protective agents.

Further, in terms of addition of a material surfactant, comparison of Example 3, which used a material surfactant heated to and kept at 43° C., and Example 13, which used a material surfactant kept at room temperature, confirmed that use of a heated surfactant tends to provide improved transmittance of a substrate protective agent.

### Testing Example 2

### <Preparation of Polishing Composition>

### Example 14

A substrate protective agent according to Example 3 in Testing Example 1 was prepared. In addition, an abrasive, ammonia, and deionized water were mixed to prepare an abrasive-containing liquid. As the abrasive, colloidal silica with an average primary particle diameter of 35 nm was used. The abrasive-containing liquid and the substrate protective agent according to Example 3 in Testing Example 1 were mixed, thereby preparing a concentrate of a polishing composition according to this example.

The concentrate of a polishing composition thus obtained was diluted 20-fold by volume ratio with deionized water, thereby providing a polishing composition according to this example containing an abrasive with a content of 0.125%, ammonia with a content of 0.0050%, hydroxyethyl cellulose (HEC) with a content of 0.0100%, and polyoxyethylene decyl ether (C10PEO5) with a content of 0.0005%.

### Comparative Example 3

The polishing composition according to this example was prepared in the same manner as in Example 14, except for using a substrate protective agent according to Comparative Example 1 in Testing Example 1 instead of a substrate protective agent according to Example 3 in Testing Example 1.

### <Evaluation of Surface Quality of Polishing Surface>

### (Polishing of Silicon Wafer)

As a substrate, a silicon wafer was prepared by lapping and etching a commercially available silicon single crystal wafer (conduction type: P type; crystal orientation: <100>; COP (crystal originated particle: crystal defect) free) with a diameter of 300 mm that was then subjected to stock polishing under Polishing condition 1 as follows. The stock polishing was performed using a polishing slurry containing 1.0% abrasive (colloidal silica with an average primary particle diameter of 35 nm) and 0.068% potassium hydroxide in deionized water.

### [Polishing Condition 1]

Polishing machine: a single wafer polishing machine manufactured by Okamoto Machine Tool Works, Ltd., model “PNX-332B”
Polishing pressure: 20 kPa
Platen rotational speed: 20 rpm
Head (carrier) rotational speed: 20 rpm
Polishing pad: manufactured by Nitta Dupont Incorporated, product name “SUBA400”
Supply flow rate of polishing slurry: 1.0 L/min
Temperature of polishing slurry: 20° C.
Temperature of platen cooling water: 20° C.
Polishing time: 3 mins

Using the polishing composition according to each of the examples prepared as described above as a polishing slurry, the silicon wafer after stock polishing was polished under Polishing condition 2 as follows, and then under Polishing condition 3 as below.

### [Polishing Condition 2]

Polishing machine: a single wafer polishing machine manufactured by Okamoto Machine Tool Works, Ltd., model “PNX-332B”
Polishing pressure: 16 kPa
Platen rotational speed: 50 rpm
Head (carrier) rotational speed: 52 rpm
Polishing pad: manufactured by Fujibo Ehime Co., Ltd., product name “POLYPAS275NX”
Supply flow rate of polishing slurry: 1.5 L/min
Temperature of polishing slurry: 20° C.
Temperature of platen cooling water: 20° C.
Polishing time: 4 mins

### [Polishing Condition 3]

Polishing machine: a single wafer polishing machine manufactured by Okamoto Machine Tool Works, Ltd., model “PNX-332B”
Polishing pressure: 20 kPa
Platen rotational speed: 50 rpm
Head (carrier) rotational speed: 52 rpm
Polishing pad: manufactured by Fujibo Ehime Co., Ltd., product name “POLYPAS275NX”
Supply flow rate of polishing slurry: 1.5 L/min
Temperature of polishing slurry: 20° C.
Temperature of platen cooling water: 20° C.
Polishing time: 4 mins

The polished silicon wafer was removed from the polishing machine, and cleaned with a cleaning liquid containing NH₄OH (29%):H₂O₂ (31%):deionized water (DIW)=1:1:12 (volume ratio) (SC-1 cleaning). In detail, two cleaning tanks, a first and second tanks, were prepared, and the cleaning liquid was stored in each of the cleaning tanks and retained at 70° C. The polished silicon wafer was immersed into the first cleaning tank for 10 minutes, then into a rinsing tank for immersion into ultrapure water with ultrasonication, and immersed into the second cleaning tank for 10 minutes, then into a rinsing tank for immersion into ultrapure water with ultrasonication, and dried with a spin drier.

### <Measurement of Numbers of LPD-N>

A surface of the cleaned silicon wafer was measured for the number of LPD-N larger than 36 nm at DCO mode using a wafer testing device having the product name of “Surfscan SP5” and manufactured by KLA-Tencor Corporation (present KLA Corporation). The result thus obtained was converted to a relative value to the number of LPD-N in Comparative Example 3 as 100%, and the resultant value was put into a corresponding column in Table 2.

### <Measurement of Numbers of LPD>

A surface of the cleaned silicon wafer was measured for the number of LPD larger than 19 nm at DCO mode using a wafer testing device having the product name of “Surfscan SP5” and manufactured by KLA-Tencor Corporation (present KLA Corporation). The result thus obtained was converted to a relative value to the number of LPD in Comparative Example 3 as 100%, and the resultant value was put into a corresponding column in Table 2.

### <Measurement of Haze>

A surface of the cleaned silicon wafer was measured for haze (ppm) at DW20 mode using a wafer testing device having the product name of “Surfscan SP5” and manufactured by KLA-Tencor Corporation (present KLA Corporation). The result thus obtained was converted to a relative value to a haze value in Comparative Example 3 as 100%, and the resultant value was put into a corresponding column in Table 2.

TABLE 2

| | Number of | Number of | |
|---|---|---|---|
| | LPD-N [%] | LPD [%] | Haze [%] |
| Example 14 | 45 | 99 | 99 |
| Comparative | 100 | 100 | 100 |
| Example 3 | | | |

As shown in Table 2, the polishing composition in Example 14, which was prepared by using the substrate protective agent according to Example 3 in Testing Example 1, was confirmed to result in remarkable reduction in the number of LPD-N as compared to the polishing composition in Comparative Example 3, which was prepared by using a substrate protective agent according to Comparative Example 1 in Testing Example 1.

While specific examples of the present invention have been described above in detail, these are only illustrative, and do not limit the scope of the claims. The technologies recited in the claims include various modifications and alternations of the specific examples illustrated above.

1. A method of producing a polishing composition comprising an abrasive, a basic compound, a cellulose derivative, and a surfactant, the method comprising:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.

2. The method of producing a polishing composition according to claim 1, wherein the material surfactant is added at a raised temperature higher than room temperature in the step (B2) or the step (C1).

3. A method of producing a substrate protective agent comprising a cellulose derivative and a surfactant, the method comprising:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.

4. A substrate protective agent comprising a cellulose derivative and a surfactant, the method comprising:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.

5. A polishing composition comprising an abrasive, a basic compound, and a substrate protective agent,
wherein the substrate protective agent comprises a cellulose derivative and a surfactant,
wherein the substrate protective agent is prepared by a method comprising:
a step (A) of dissolving a material cellulose derivative in a solvent to prepare a material cellulose derivative solution; and the following steps:
a step (B1) of heating the material cellulose derivative solution and a step (B2) of adding a material surfactant to the material cellulose derivative solution that underwent the step (B1); or
a step (C1) of adding a material surfactant to the material cellulose derivative solution to prepare an additive mixture liquid and a step (C2) of heating the additive mixture liquid.

6. The polishing composition according to claim 5, used for polishing a surface formed of a silicon material.

7. A concentrate of the polishing composition according to claim 5.

8. A polishing method comprising a step of polishing a surface formed of a silicon material with use of the polishing composition according to claim 5.

9. A concentrate of the polishing composition according to claim 6.

10. A polishing method comprising a step of polishing a surface formed of a silicon material with use of the polishing composition according to claim 6.
